(19) United States
(12) Patent Application Publication
(10) Pub. No.: US 2014/0285225 A1
(43) Pub. Date: Sep. 25, 2014

(54) APPARATUS FOR DETERMINING TYPE OF ANALOG SENSOR

(71) Applicant: SAMSUNG SDS CO., LTD., Seoul (KR)

(72) Inventors: Ji Hun CHO, Seongnam-si (KR); Young KWAK, Gwangmyeong-si (KR)

(73) Assignee: SAMSUNG SDS CO., LTD., Seoul (KR)

(21) Appl. No.: 14/068,598

(22) Filed: Oct. 31, 2013

(30) Foreign Application Priority Data
Mar. 19, 2013 (KR) 10-2013-0029310

(51) Int. Cl. G01R 19/00

(52) U.S. Cl. CPC G01R 19/0046
USPC 324/705

(57) ABSTRACT

Provided is an apparatus for determining the type of an analog sensor. The apparatus for determining the type of an analog sensor includes a determination module configured to receive an output signal output from the sensor and output a determination reference signal for determining the type of the sensor, and a controller configured to apply the output signal from the sensor to the determination module and determine the type of the sensor using the determination reference signal output from the determination module.

### CROSS-REFERENCE TO RELATED APPLICATION

This application claims priority to and the benefit of Republic of Korea Patent Application No. 10-2013-0029310, filed on Mar. 19, 2013, the disclosure of which is incorporated herein by reference in its entirety.

### BACKGROUND

1. Field

The present disclosure relates to technology for determining the type of an analog sensor using a characteristic of the sensor, and more particularly, to an apparatus for determining the type of an analog sensor.

2. Discussion of Related Art

A building management system (BMS) denotes a system for comprehensively managing and controlling respective functions in a building including an air conditioning system, illumination, etc. in the building. Such a BMS involves various analog sensors, such as a temperature sensor, a humidity sensor, an illumination sensor, etc., capable of sensing conditions in a building.

Analog sensors may be classified into a resistance output sensor, a voltage output sensor, and a current output sensor according to their methods of outputting a sensed value. The resistance output sensor denotes a sensor whose internal resistance value varies according to a sensed value, and a resistance temperature detector (RTD) sensor whose resistance value varies according to variance in an ambient temperature may be an example. Also, the voltage output sensor denotes a sensor whose output voltage varies according to a sensed value, and the current output sensor denotes a sensor whose output current varies according to a sensed value. Output values of these analog sensors are applied to a central processing unit (CPU), subjected to an appropriate processing process, and used for controlling a building.

FIG. 1 is a diagram illustrating connection between general analog sensors and a CPU. As shown in the drawing, existing analog sensors are configured so that their output values are applied to a multiplexer 104 through a jumper 102, subjected to a multiplexing process at the multiplexer 104, and then input to a CPU. Here, the jumper 102 is a circuit for recording a setting value for determining the type of each sensor, that is, which one of a resistance output sensor, a voltage output sensor, and a current output sensor the corresponding sensor is. In other words, in case of existing analog sensors, a manager should manually set the types of analog sensors by setting jumper values one by one, and thus management of the analog sensors is very inconvenient. Also, when the manager makes a mistake in jumper setting, it frequently becomes impossible to properly read outputs of the sensors, and also a problem frequently occurs in an overall circuit.

In addition, the existing analog sensor is kept connected to the multiplexer 104 through the jumper 102 as shown in the drawing, and thus, when abnormally high voltage is applied due to a fault of the sensor, etc., damage may occur in subsequent circuits as well as the multiplexer 104.

### SUMMARY

Aspects of the present disclosure are directed to providing a means for automatically determining the type of a connected analog sensor.

According to an aspect of the present disclosure, there is provided an apparatus for determining the type of an analog sensor including: a determination module configured to receive an output signal output from the sensor, and output a determination reference signal for determining the type of the sensor; and a controller configured to apply the output signal from the sensor to the determination module, and determine the type of the sensor using the determination reference signal output from the determination module.

### BRIEF DESCRIPTION OF THE DRAWINGS

The above and other objects, features, and advantages of the present disclosure will become more apparent to those of ordinary skill in the art by describing in detail exemplary embodiments thereof with reference to the accompanying drawings, in which:

FIG. 1 is a diagram illustrating connection between general analog sensors and a central processing unit (CPU);

FIG. 2 is a block diagram illustrating a constitution of an apparatus for determining the type of an analog sensor according to an exemplary embodiment of the present disclosure;

FIG. 3 is a diagram illustrating a detailed constitution of a resistance input sensing unit according to an exemplary embodiment of the present disclosure;

FIG. 4 is a diagram illustrating a detailed constitution of a voltage input sensing unit according to an exemplary embodiment of the present disclosure;

FIG. 5 is a diagram illustrating a detailed constitution of a current input sensing unit according to an exemplary embodiment of the present disclosure; and

FIG. 6 is a flowchart illustrating a method of controlling an apparatus for determining the type of an analog sensor according to an exemplary embodiment of the present disclosure.

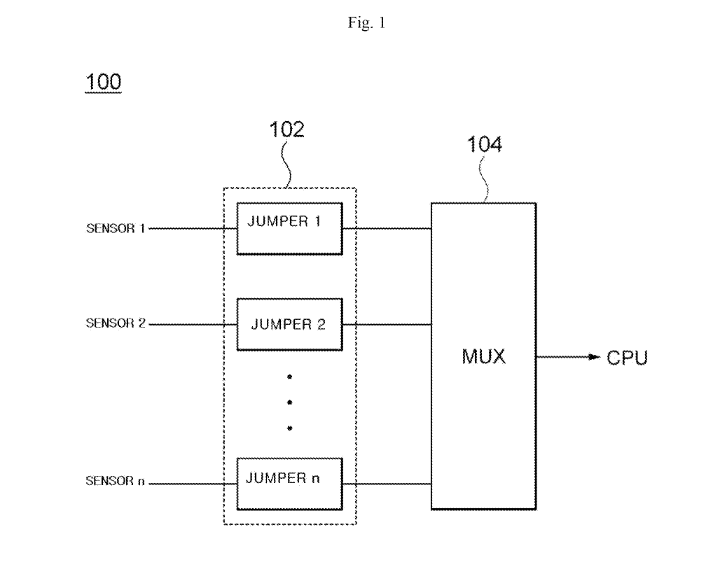

### DETAILED DESCRIPTION OF EXEMPLARY EMBODIMENTS

Hereinafter, detailed embodiments of the present disclosure will be described with reference to the accompanying drawings. However, the embodiments are merely examples and are not to be construed as limiting the present disclosure.

When it is determined that the detailed description of known art related to the present disclosure may obscure the gist of the present disclosure, the detailed description thereof will be omitted. Terminology described below is defined considering functions in the present disclosure and may vary according to a user's or operator's intention or usual practice. Thus, the meanings of the terminology should be interpreted based on the overall context of the present specification.

The spirit of the present disclosure is determined by the claims, and the following exemplary embodiments are provided only to efficiently describe the spirit of the present disclosure to those of ordinary skill in the art.

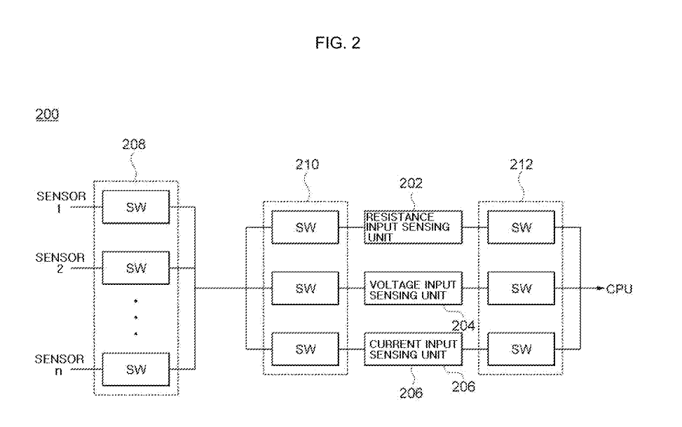

FIG. 2 is a block diagram illustrating a constitution of an apparatus for determining the type of an analog sensor according to an exemplary embodiment of the present disclosure. As shown in the drawing, an apparatus 200 for determining the type of an analog sensor according to an exemplary embodiment of the present disclosure is provided between analog sensors and a central processing unit (CPU) for processing output values of the analog sensors, and configured to automatically determine the type of a connected analog sensor so that the CPU performs signal processing according to the type of the connected analog sensor. As shown in the drawing, the apparatus 200 for determining the type of an analog sensor according to an exemplary embodiment of the present disclosure includes a resistance input sensing unit 202, a voltage input sensing unit 204, and a current input sensing unit 206.

In an exemplary embodiment of the present disclosure, the resistance input sensing unit 202, the voltage input sensing unit 204, and the current input sensing unit 206 constitute a determination module for determining the type of a sensor from a sensor output. In other words, the determination module is configured to receive an output signal output from a sensor, and output a determination reference signal for determining the type of the sensor.

In the exemplary embodiment shown in the drawing, the determination module includes all of the resistance input sensing unit 202, the voltage input sensing unit 204, and the current input sensing unit 206. However, this constitution is merely an example, and depending on a characteristic of a connected sensor, some of the resistance input sensing unit 202, the voltage input sensing unit 204, and the current input sensing unit 206 may be omitted in determination modules according to exemplary embodiments of the present disclosure. In other words, it is to be noted that various modifications, such as a determination module consisting of the resistance input sensing unit 202 alone, a determination module consisting of only the voltage input sensing unit 204 and the current input sensing unit 206, etc., are available, and are all included in the scope of the present disclosure.

The resistance input sensing unit 202 outputs a first determination reference signal for determining whether or not an analog sensor is a resistance output sensor from an output signal output from the analog sensor. Also, the voltage input sensing unit 204 outputs a second determination reference signal for determining whether or not the analog sensor is a voltage output sensor from the output signal, and the current input sensing unit 206 outputs a third determination reference signal for determining whether or not the analog sensor is a current output sensor from the output signal.

In exemplary embodiments of the present disclosure, an analog sensor (for brevity, referred to as a sensor below) denotes a sensor whose sensed value is not output in a digital form but is output in an analog form. According to characteristics of their output values, analog sensors are classified into a resistance output sensor, a voltage output sensor, and a current output sensor. The resistance output sensor denotes a sensor whose internal resistance value varies according to a sensed value, and a resistance temperature detector (RTD) sensor whose resistance value varies according to variance in an ambient temperature may be an example. Also, the voltage output sensor denotes a sensor whose output voltage varies according to a sensed value, and the current output sensor denotes a sensor whose output current varies according to a sensed value. Using these characteristics of a resistance output sensor, a voltage output sensor, and a current output sensor, the resistance input sensing unit 202, the voltage input sensing unit 204, and the current input sensing unit 206 determine whether or not a connected sensor is a resistance output sensor, whether or not the connected sensor is a voltage output sensor, and whether or not the connected sensor is a current output sensor, respectively.

The apparatus 200 for determining the type of an analog sensor according to an exemplary embodiment of the present disclosure may be configured to receive sensed values from a plurality of sensors (n sensors) in parallel, and determine the types of the respective sensors. To this end, as shown in the drawing, a first switching module 208 may be further provided between the apparatus 200 for determining the type of an analog sensor according to an exemplary embodiment of the present disclosure and the plurality of sensors. The first switching module 208 includes n switches that are connected to output ends of the plurality of sensors respectively. By repeatedly turning on/off the n switches in sequence according to control of the CPU, the first switching module 208 sequentially applies respective sensed values to the apparatus 200 for determining the type of an analog sensor. For example, by sequentially turning on the respective switches for a time T/n at periods T, the first switching module 208 may sequentially output sensed values of the respective sensors. When the one apparatus 200 is configured in this way, it is possible to determine the types of a plurality of sensors using the one apparatus 200 for determining the type of an analog sensor. Also, output values of the respective sensors are not always output to the CPU but are output for a limited time T/n according to control of the first switching module 208, and the first switching module 208 is kept in an off state at other times. Thus, even when abnormally high voltage is applied due to a fault of a sensor, etc., it is possible to prevent other circuits from being damaged.

In addition, the apparatus 200 for determining the type of an analog sensor according to an exemplary embodiment of the present disclosure further includes a controller (not shown) for controlling the resistance input sensing unit 202, the voltage input sensing unit 204, and the current input sensing unit 206 described above. The controller is configured to determine the type of a sensor by sequentially applying an output signal from the sensor to the resistance input sensing unit 202, the voltage input sensing unit 204, and the current input sensing unit 206. Such a controller may be implemented as separate hardware, or the CPU may perform functions of the controller.

To sequentially apply an output signal from a sensor, the apparatus 200 for determining the type of the analog sensor according to an exemplary embodiment of the present disclosure may further include a second switching module 210 and a third switching module 212. As shown in FIG. 2, the second switching module 210 and the third switching module 212 are respectively connected to front ends and rear ends of the resistance input sensing unit 202, the voltage input sensing unit 204, and the current input sensing unit 206. The controller controls each of the second switching module 210 and the third switching module 212 so that an output from a sensor can be sequentially applied to the resistance input sensing unit 202, the voltage input sensing unit 204, and the current input sensing unit 206. For example, when an output from a sensor is applied to the resistance input sensing unit 202, switches at the both ends of the resistance input sensing unit 202 are turned on, and other switches of the second switching module 210 and the third switching module 212 are kept in the off state. In this way, switches are installed at both ends of each sensing unit to prevent a sensor type sensed by a specific sensing unit from being affected by a circuit included in another sensing unit.

Detailed constitutions of the resistance input sensing unit 202, the voltage input sensing unit 204, and the current input sensing unit 206 will be described below.

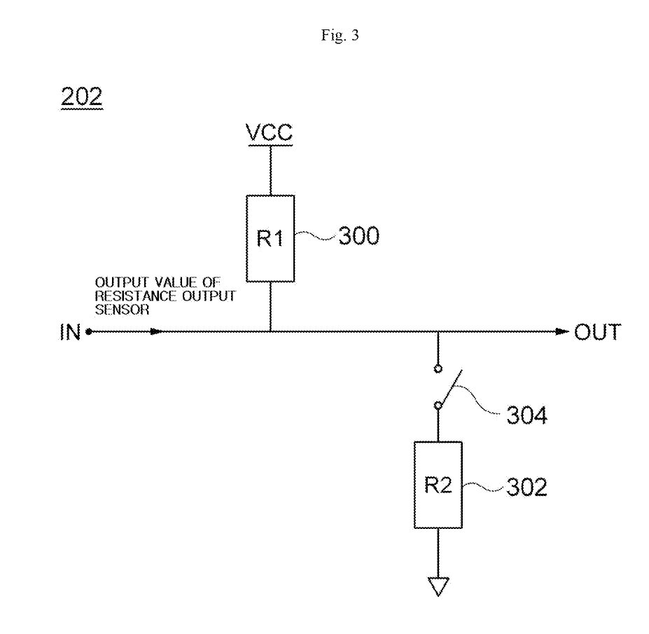

FIG. 3 is a diagram illustrating a detailed constitution of a resistance input sensing unit according to an exemplary embodiment of the present disclosure. The resistance input sensing unit 202 is configured to determine whether or not an analog sensor is a resistance output sensor according to whether or not voltage output from the resistance input sensing unit 202 varies when a test resistor is connected between an output end of the sensor and a ground end. As shown in the drawing, the resistance input sensing unit 202 according to an exemplary embodiment of the present disclosure includes a first resistor 300, a second resistor 302, and a first switch 304.

One end of the first resistor 300 is connected to a drive voltage supply end Vcc, and the other end is connected to an output end of a sensor. One end of the second resistor 302 is grounded, and the other end is connected to the output end of the sensor through the first switch 304. The first switch 304 is provided between the other end of the second resistor 302 and the output end of the sensor, and configured to turn on/off a connection between the other end of the second resistor 302 and the output end of the sensor according to control of the controller.

The resistance input sensing unit 202 constituted as described above operates as follows. When a sensor connected to the resistance input sensing unit 202 is a resistance output sensor, the sensor may be regarded as a resistor having a specific resistance value. Suppose that a resistance of the sensor is R, a resistance of the first resistor 300 is R1, and a resistance of the second resistor 302 is R2. When the first switch 304 is in an off state, a voltage V1 measured at an output end OUT of the resistance input sensing unit 202 is calculated as follows:

V1=Vcc*(R/(R+R1))

Also, when the first switch 304 is in an on state, that is, when the second resistor 302 is connected, a voltage V2 measured at the output end OUT of the resistance input sensing unit 202 is calculated as follows:

V2=Vcc*((R*R2)/(R+R2))/(R1+(R*R2)/(R+R2))

In other words, when the sensor connected to the resistance input sensing unit 202 is a resistance output sensor, a resultant resistance of the overall circuit varies according to whether or not the second resistor 302 is connected, and according to the resultant resistance, voltage output from the output end OUT of the resistance input sensing unit 202 also varies (V1≠V2). In other words, using the second resistor 302 as a test resistor, the resistance input sensing unit 202 outputs a voltage of an output signal measured when the first switch 304 is in the on state and a voltage measured when the first switch 304 is in the off state as first determination reference signals, and the controller determines the connected sensor as a resistance output sensor when the two output values are different.

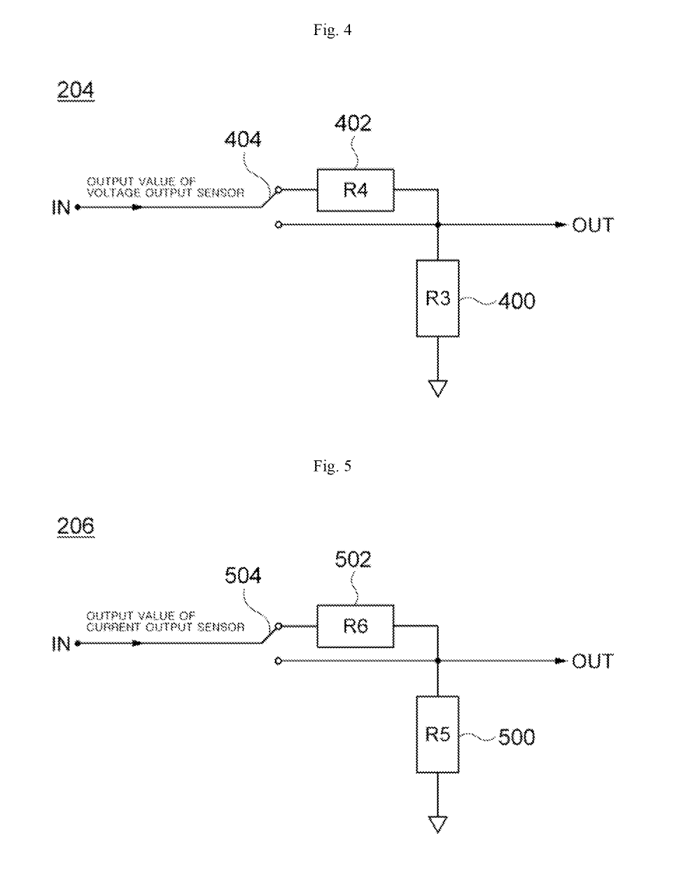

FIG. 4 is a diagram illustrating a detailed constitution of a voltage input sensing unit according to an exemplary embodiment of the present disclosure. The voltage input sensing unit 204 is configured to determine whether or not a connected sensor is a voltage output sensor according to whether or not voltage output from the voltage input sensing unit 204 varies when a test resistor is connected between an output end of the sensor and an output end of the voltage input sensing unit 204. As shown in the drawing, the voltage input sensing unit 204 according to an exemplary embodiment of the present disclosure includes a third resistor 400, a fourth resistor 402, and a second switch 404.

One end of the third resistor 400 is grounded, and the other end is connected to the output end of the voltage input sensing unit 204. One end of the fourth resistor 402 is connected to the other end of the third resistor 400, and the other end is connected to the second switch 404. The second switch 404 is configured to selectively connect the output end of the sensor to one of the other end of the fourth resistor 402 and the other end of the third resistor 400 according to control of the controller. In other words, an output value of the connected sensor passes through or bypasses the fourth resistor 402 according to switching of the second switch 404. The third resistor 400 and the fourth resistor 402 have high resistance values of about 100 kilo ohm or more.

The voltage input sensing unit 204 constituted as described above operates as follows. When the second switch 404 is in the off state, that is, the output value of the sensor is directly connected to the output end of the voltage input sensing unit 204, a voltage V3 at the output end of the voltage input sensing unit 204 is the same as a voltage Vin of a signal applied to the voltage input sensing unit 204. In other words, the both voltages have the following relationship:

V3=Vin

Also, when the second switch 404 is in the on state, that is, the output value of the sensor passes through the fourth resistor 402, the input voltage Vin and an output voltage V4 have the following relationship:

V4=Vin*R3/(R3+R4)

When the sensor connected to the voltage input sensing unit 204 is a voltage output sensor, and connected to the fourth resistor 402 by operation of the second switch 404, a voltage drop occurs. Thus, according to operation of the second switch 404, the output voltage of the voltage input sensing unit 204 varies (V3≠V4). When R3 equals R4, connection of the fourth resistor 402 drops the output voltage of the voltage input sensing unit 204 by half. However, when the sensor is a current output sensor, considering that an output value of the current output sensor ranges from about 4 mA to about 20 mA, a high voltage of about several hundred volts is applied to the output end of the voltage input sensing unit 204 regardless of whether or not the fourth resistor 402 is connected (assuming that R3 is 100 KΩ, a measured voltage of the output end theoretically becomes 400 V at an output of 4 mA). In other words, the voltage input sensing unit 204 outputs the output voltages V3 and V4 as second determination reference signals, and the controller may determine whether or not the connected sensor is a voltage output sensor by measuring a voltage change at the output end of the voltage input sensing unit 204 (difference between V3 and V4) according to connection states of the second switch 404.

FIG. 5 is a diagram illustrating a detailed constitution of a current input sensing unit according to an exemplary embodiment of the present disclosure. The current input sensing unit 206 is configured to determine whether or not a connected sensor is a current output sensor according to whether or not voltage output from the current input sensing unit 206 varies when a test resistor is connected between an output end of the sensor and an output end of the current input sensing unit 206. As shown in the drawing, the current input sensing unit 206 according to an exemplary embodiment of the present disclosure includes a fifth resistor 500, a sixth resistor 502, and a third switch 504.

One end of the fifth resistor 500 is grounded, and the other end is connected to the output end of the current input sensing unit 206. One end of the sixth resistor 502 is connected to the other end of the fifth resistor 500, and the other end is connected to the third switch 504. The third switch 504 is configured to selectively connect the output end of the sensor to one of the other end of the sixth resistor 502 and the other end of the fifth resistor 500 according to control of the controller. In other words, an output value of the connected sensor passes through or bypasses the sixth resistor 502 according to switching of the third switch 504. Unlike in the voltage input sensing unit 204, in the current input sensing unit 206, the fifth resistor 500 and the sixth resistor 502 have low resistance values of about tens of ohm, which are intended to make a voltage measured at the output end several volts (accurately, less than or equal to Vcc) considering that an output value of a current output sensor ranges from about 4 mA to about 20 mA.

The current input sensing unit 206 constituted as described above operates as follows. Suppose that a sensor connected to the current input sensing unit 206 is a current output sensor. Since a current does not vary in value even when passing through a resistor, a voltage Vout at the output end of the current input sensing unit 206 is determined according to a resistance value R5 of the fifth resistor 500 regardless of whether the third switch 504 is turned on or off. In other words, when an input current is Iin, the voltage Vout is calculated as follows:

Vout=R5*Iin

In other words, the current input sensing unit 206 outputs a voltage change at the current output end according to connection states of the third switch 504 as a third determination reference signal, and the controller may determine the connected sensor as a current output sensor when a fixed voltage is output from the current input sensing unit 206 regardless of the connection states.

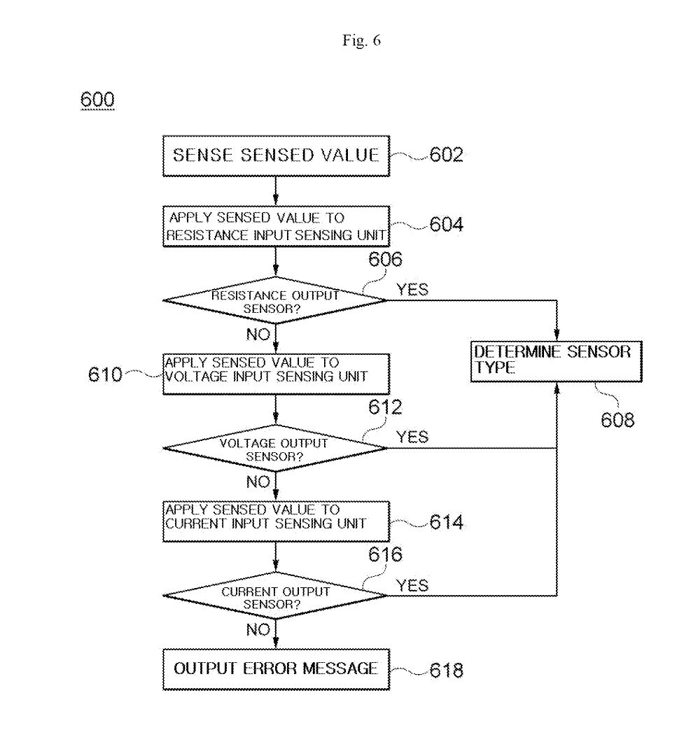

FIG. 6 is a flowchart illustrating a method of controlling an apparatus for determining the type of an analog sensor according to an exemplary embodiment of the present disclosure.

When an input of a sensed value from a connected sensor is sensed (602), the controller controls the second switching module 210 and the third switching module 212 to apply the sensed value to the resistance input sensing unit 202 (604). Next, the controller measures respective output voltages (first determination reference signals) of the resistance input sensing unit 202 when the first switch 304 of the resistance input sensing unit 202 is turned on/off, and determines whether or not the sensor is a resistance output sensor according to whether the two values are the same or different (606). As mentioned above, the controller may determine the sensor as a resistance output sensor when the output voltage varies upon connection of the first switch 304.

When it is determined in step 606 that the connected sensor is a resistance output sensor, the controller sets the type of the sensor in the CPU (608). On the other hand, when it is determined that the connected sensor is not a resistance output sensor, the controller controls the second switching module 210 and the third switching module 212 to apply the sensed value to the voltage input sensing unit 204 (610). Subsequently, the controller measures respective output voltages (second determination reference signals) of the voltage input sensing unit 204 when the second switch 404 of the voltage input sensing unit 204 is turned on/off, and determines whether or not the sensor is a voltage output sensor according to whether the two values are the same or different (612). As mentioned above, the controller may determine the sensor as a voltage output sensor when the output voltage varies upon connection of the second switch 404.

When it is determined in step 612 that the connected sensor is a voltage output sensor, the controller sets the type of the sensor in the CPU (608). On the other hand, when it is determined that the connected sensor is not a voltage output sensor, the controller controls the second switching module 210 and the third switching module 212 to apply the sensed value to the current input sensing unit 206 (614). Subsequently, the controller measures respective output voltages (third determination reference signals) of the current input sensing unit 206 when the third switch 504 of the current input sensing unit 206 is turned on/off, and determines whether or not the sensor is a current output sensor according to whether the two values are the same or different (616). As mentioned above, the controller may determine the sensor as a current output sensor when the output voltage does not vary despite connection of the third switch 504.

When it is determined in step 616 that the connected sensor is a current output sensor, the controller sets the type of the sensor in the CPU (608). On the other hand, when it is determined that the connected sensor is not a current output sensor, it is determined that a normal value has not been output, and an error message is output (618).

In exemplary embodiments of the present disclosure, the type of a connected analog sensor can be automatically determined according to a characteristic of an output value of the sensor. Thus, it is possible to accurately find the type of each sensor without manual setting by a manager.

In addition, in exemplary embodiments of the present disclosure, an input from a sensor is passed only to read a value of the sensor and blocked at other times so that damage to a circuit can be minimized even when an abnormal value is applied from the sensor.

It will be apparent to those skilled in the art that various modifications can be made to the above-described exemplary embodiments of the present disclosure without departing from the spirit or scope of the present disclosure. Thus, it is intended that the present disclosure covers all such modifications provided they come within the scope of the appended claims and their equivalents.

What is claimed is:

1. An apparatus for determining an analog sensor type, comprising:
a determination module configured to receive an analog sensor output signal, and to output a determination reference signal; and
a controller configured to apply the analog sensor output signal to the determination module, and to determine the analog sensor type using the determination reference signal.

2. The apparatus of claim 1, wherein the determination module includes at least one of:
a resistance input sensing unit configured to output a first determination reference signal for determining, from the analog sensor output signal, whether the analog sensor type is a resistance output sensor type;
a voltage input sensing unit configured to output a second determination reference signal for determining, from the analog sensor output signal, whether the analog sensor type is a voltage output sensor type; and
a current input sensing unit configured to output a third determination reference signal for determining, from the analog sensor output signal, whether the analog sensor type is a current output sensor type.

3. The apparatus of claim 2, wherein the resistance input sensing unit is further configured to determine whether the analog sensor type is the resistance output sensor type according to whether a voltage, output from the resistance input sensing unit, varies when a test resistor is between an analog sensor output end and a ground end.

4. The apparatus of claim 2, wherein the resistance input sensing unit includes:
a first resistor having a first end connected to a drive voltage supply end and having a second end connected to an analog sensor output end;
a second resistor having a first end grounded and having a second end connected to the analog sensor output end; and
a first switch, under control of the controller, between the second end of the second resistor and the analog output sensor end, configured to switch a connection between the second end of the second resistor and the analog sensor output end.

5. The apparatus of claim 4, wherein the controller is further configured to control the first switch, so as to determine that the analog sensor type is the resistance output sensor type, in response to detecting a difference between:
a voltage of the analog sensor output signal, measured when the first switch is in an on state, and
a voltage measured when the first switch is in an off state.

6. The apparatus of claim 2, wherein the voltage input sensing unit is further configured to determine that the analog sensor type is the voltage output sensor type according to whether a voltage output from the voltage input sensing unit varies when a test resistor is connected between an analog sensor output end and an output end of the voltage input sensing unit.

7. The apparatus of claim 2, wherein the voltage input sensing unit includes:
a third resistor having a first end grounded and a second end connected to an output end of the voltage input sensing unit;
a fourth resistor having a first end connected to the second end of the third resistor; and
a second switch, under control of the controller, configured to selectively connect an analog sensor output end to one of:
the second end of the fourth resistor, and
the second end of the third resistor.

8. The apparatus of claim 7, wherein the controller is further configured to control the second switch, so as to determine that the analog sensor type is the voltage output sensor type, in response to detecting a difference between:
a voltage measured when the analog sensor output end is connected to the second end of the fourth resistor and
a voltage measured when the analog sensor output end is connected to the second end of the third resistor.

9. The apparatus of claim 2, wherein the current input sensing unit is further configured to determine whether the analog sensor type is the current output sensor type according to whether a voltage output from the current input sensing unit varies when a test resistor is connected between an analog sensor output end and an output end of the current input sensing unit.

10. The apparatus of claim 2, wherein the current input sensing unit includes:
a fifth resistor having a first end grounded and a second end connected to an output end of the current input sensing unit;
a sixth resistor having a first end connected to the second end of the fifth resistor; and
a third switch, under control of the controller, configured to selectively connect an analog sensor output end to one of:
the second end of the sixth resistor and
the second end of the fifth resistor.

11. The apparatus of claim 10, wherein the controller is further configured to control the third switch, so as to determine that the analog sensor type is the current output sensor type, in response to detecting a similarity between:
a voltage measured when the analog sensor output end is connected to the second end of the sixth resistor and
a voltage measured when the analog sensor output end is connected to the second end of the fifth resistor.
